(19) United States
(12) Patent Application Publication
(10) Pub. No.: US 2024/0153910 A1
(43) Pub. Date: May 9, 2024

(54) FERROMAGNETIC CONTROL OF WAFER BONDING

(71) Applicant: Micron Technolgy, Inc., Boise, ID (US)

(72) Inventor: Andrew M. BAYLESS, Boise, ID (US)

(21) Appl. No.: 18/496,572

(22) Filed: Oct. 27, 2023

Related U.S. Application Data
(60) Provisional application No. 63/382,930, filed on Nov. 9, 2022.

(51) Int. Cl. H01L 23/00; H01L 25/00; H01L 25/065; H10B 80/00

(52) U.S. Cl. CPC H01L 24/83; H01L 24/29; H01L 24/743; H01L 25/0657; H01L 25/50; H10B 80/00; H01L 2224/29023; H01L 2224/291; H01L 2224/743; H01L 2224/8322; H01L 2225/06524; H01L 2225/06527

(57) ABSTRACT

Implementations described herein relate to various semiconductor device assemblies. In some implementations, a semiconductor device assembly may include a first semiconductor die, a second semiconductor die in a stacked arrangement with the first semiconductor die, and a layer of ferromagnetic material disposed between the first semiconductor die and the second semiconductor die.

### CROSS-REFERENCE TO RELATED APPLICATION

This Patent Application claims priority to U.S. Provisional Patent Application No. 63/382,930, filed on Nov. 9, 2022, and entitled “FERROMAGNETIC CONTROL OF WAFER BONDING.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to ferromagnetic control of wafer bonding.

### BACKGROUND

A semiconductor package includes a casing that contains one or more semiconductor devices, such as integrated circuits. Semiconductor device components may be fabricated on semiconductor wafers before being diced into dies and then packaged. A semiconductor package protects internal components from damage and includes means for connecting internal components to external components (e.g., a circuit board), such as via balls, pins, or leads. A semiconductor package is sometimes referred to as a semiconductor device assembly.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example bonding device.

FIGS. 4-6 are diagrams illustrating an example associated with ferromagnetic control of wafer bonding.

FIG. 7 is a diagram of an example semiconductor device assembly.

FIG. 8 is a diagram of an example semiconductor device assembly.

FIG. 9 is a flowchart of an example method of forming an integrated assembly or memory device having a layer of ferromagnetic material.

FIG. 10 is a flowchart of an example method of forming an integrated assembly or memory device having a layer of ferromagnetic material.

### DETAILED DESCRIPTION

Wafer bonding includes various techniques for joining two or more wafers together to form a composite structure. One technique is fusion bonding, in which two or more wafers, usually made of silicon or another semiconductor material, are bonded together via chemical bonds. In fusion bonding, wafers may be mounted on opposing chucks of a bonding device and controlled by vacuum, and air pressure and/or a mechanical actuator (e.g., a pin) may be used to initiate and control contact (e.g., a bond wave) between the wafers. For example, the air pressure and/or the mechanical actuator may be used to flex or bow one wafer toward another wafer to initiate bonding at a center of the wafers and to control bonding from the center of the wafers to edges of the wafers. However, the air pressure and/or the mechanical actuator may provide imprecise control of the bonding (e.g., the bond wave), thereby resulting in a low-quality bond, misalignment of the wafers, and/or distortion. For example, an alignment accuracy that can be achieved using the air pressure and/or the mechanical actuator may be about 75 nanometers (nm). Semiconductor devices produced from such poorly bonded wafers may exhibit poor performance and/or may have a short useful life.

Some implementations described herein enable ferromagnetic control of wafer bonding. In some implementations, at least one of multiple wafers to be bonded may include a layer of ferromagnetic material. In some implementations, one or more chucks of a bonding device may be configured to produce magnetic fields (e.g., the chuck(s) may include electromagnets). Accordingly, when the wafers are mounted on the chucks, the magnetic fields may be controlled (e.g., the electromagnets may be activated) to interact with the layer of ferromagnetic material in a particular manner to cause bonding (e.g., fusion bonding) of the wafers. For example, the magnetic fields may be controlled to repel and/or attract the layer of ferromagnetic material, to thereby flex or bow the wafer to initiate and control bonding of the wafers, in a similar manner as described above. In this way, bonding (e.g., a bond wave) between the wafers may be precisely controlled, thereby improving an alignment and bond quality of the wafers (e.g., based on a post-bonding alignment overlay indicating an amount of misalignment between alignment marks on bonded wafers). For example, an alignment accuracy that can be achieved using ferromagnetic control may be about 10 nm. Accordingly, the bonded wafers may be used to produce semiconductor devices with improved performance and longer useful life.

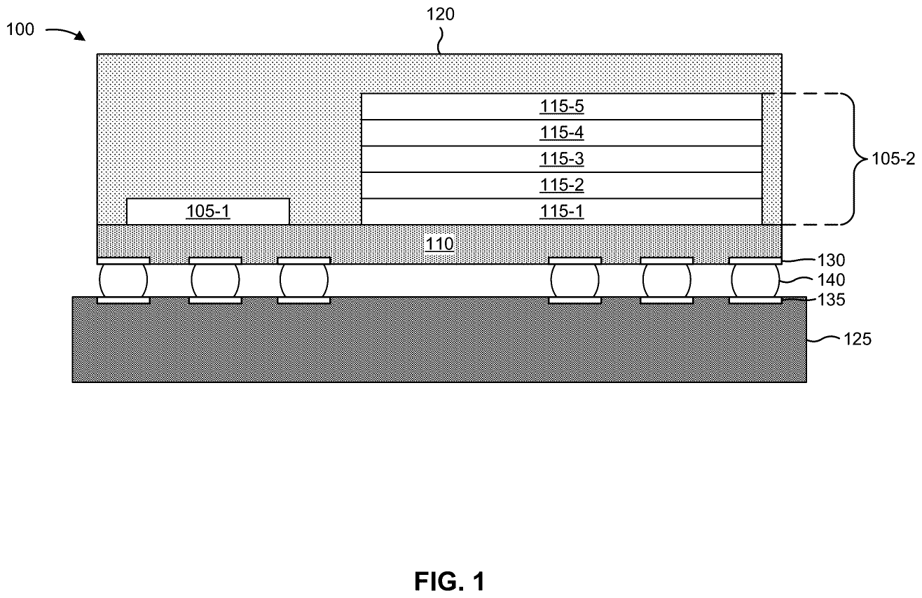

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a high bandwidth memory (HBM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include multiple semiconductor dies 115 (sometimes called dies), shown as five semiconductor dies 115-1 through 115-5. As shown in FIG. 1, the dies 115 may be stacked on top of each other to reduce a footprint of the apparatus 100 (e.g., using wafer-on-wafer (WoW) stacking or chip-on-wafer (CoW) stacking). The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

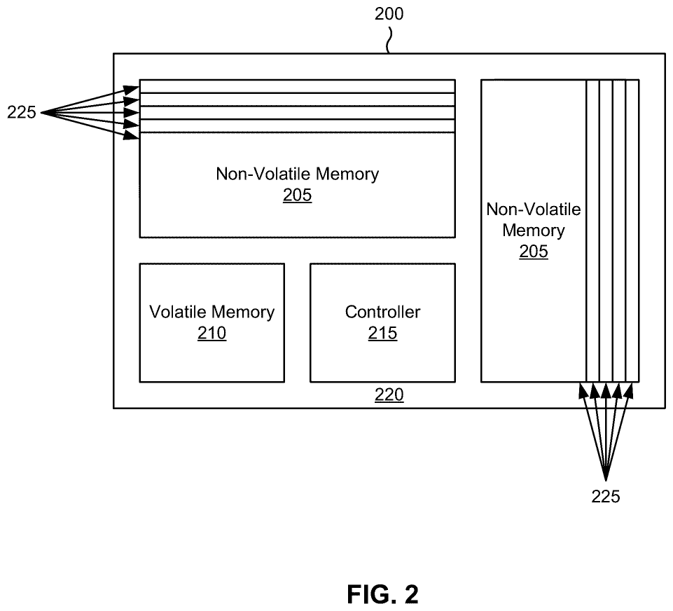

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

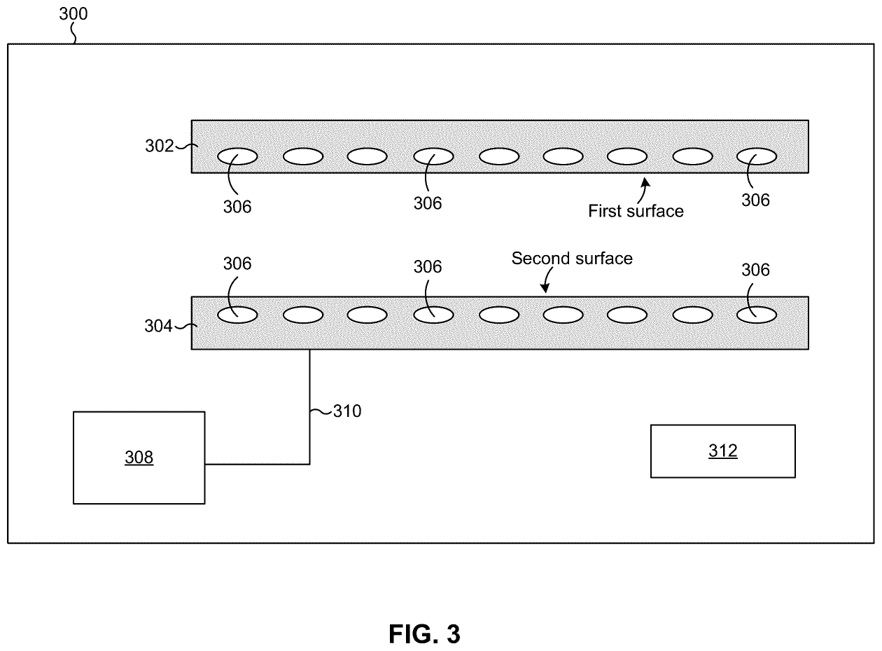

FIG. 3 is a diagram of an example bonding device 300. The bonding device 300 may also be referred to as a “wafer bonding device,” “wafer bonding equipment,” or the like. As shown, the bonding device 300 may include a first chuck 302 (e.g., a top chuck) and a second chuck 304 (e.g., a bottom chuck). The chucks 302, 304 (e.g., bond chucks) may be supports, such as plates, on which semiconductor devices (e.g., semiconductor wafers) may be mounted for bonding. For example, the first chuck 302 may be configured to retain a first semiconductor device (e.g., a first semiconductor wafer), as described herein, at a first surface of the first chuck 302, and the second chuck 304 may be configured to retain a second semiconductor device (e.g., a second semiconductor wafer), as described herein, at a second surface of the second chuck 304. As shown, the chucks 302, 304 may oppose one another. For example, the first surface of the first chuck 302 may face the second surface of the second chuck 304.

The bonding device 300 may be configured to produce magnetic fields. For example, the bonding device 300 may include a plurality of electromagnets 306 joined with the first chuck 302 and/or the second chuck 304. As an example, the electromagnets 306 may be embedded in the first chuck 302 and/or the second chuck 304, and/or the electromagnets 306 may be disposed on the first chuck 302 (e.g., on a back surface of the first chuck 302 opposite the first surface) and/or the second chuck 304 (e.g., on a back surface of the second chuck 304 opposite the second surface). In some implementations, a first plurality of electromagnets 306 may be joined with the first chuck 302, and a second plurality of electromagnets 306 may be joined with the second chuck 304. In some implementations, the electromagnets 306 of a chuck 302 or 304 may be arranged in a grid. For example, the first plurality of electromagnets 306 of the first chuck 302 may be arranged in a grid, and the second plurality of electromagnets 306 of the second chuck 304 may be arranged in a grid.

The electromagnets 306 may be individually addressable. For example, control circuitry of the bonding device 300 may be configured to enable each electromagnet 306 to be individually activated or deactivated, as well as individually activated to a particular intensity (e.g., by controlling electrical current to the electromagnet 306). The electromagnets 306 may be configured to generate magnetic fields of a strength sufficient to repel or attract a ferromagnetic material layer, as described herein, of the first semiconductor device.

In some implementations, the bonding device 300 may include a vacuum device 308 (e.g., a vacuum source). As shown, the vacuum device 308 may be connected to the second chuck 304 via a vacuum line 310. The second chuck 304 may include a plurality of openings (not shown) in the second surface of the second chuck 304 that are in fluid communication with the vacuum line 310. In operation, the vacuum device 308 may create suction at the second surface, via the plurality of openings, to retain the second semiconductor device to the second chuck 304. In some implementations, the vacuum device 308, or an additional vacuum device, may be connected to the first chuck 302 via an additional vacuum line, and the first surface of the first chuck 302 may include a plurality of openings in fluid communication with the vacuum line, in a similar manner as described above. Here, in operation, the vacuum device 308, or the additional vacuum device, may create suction at the first surface, via the plurality of openings, to retain the first semiconductor device to the first chuck 302. Additionally, or alternatively, magnetic fields produced by the electromagnets 306 may be used to retain the first semiconductor device to the first chuck 302.

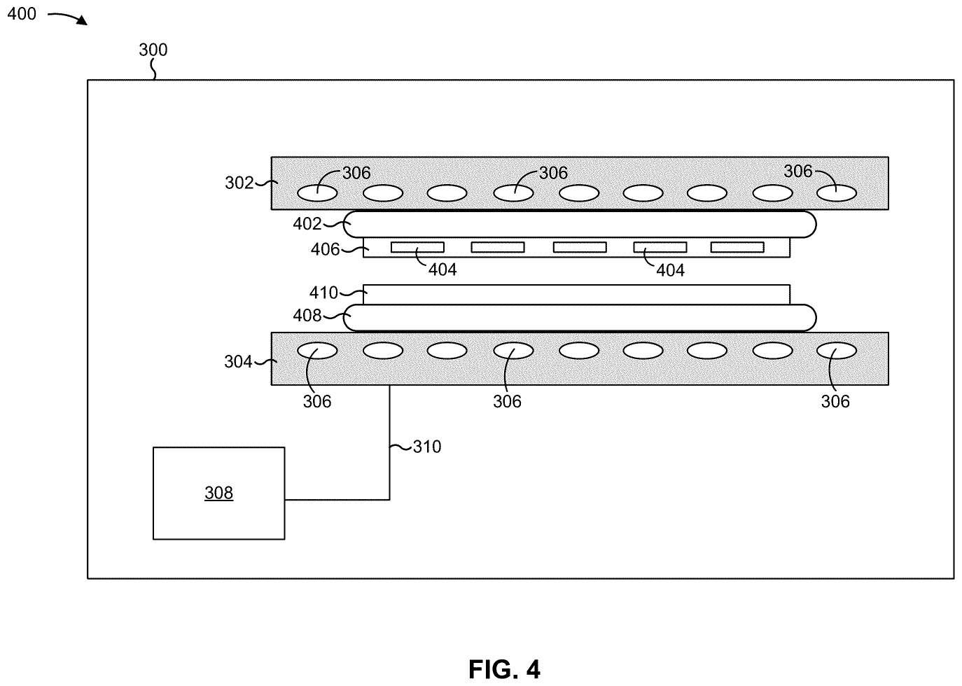

In some implementations, the bonding device 300 may include a controller 312. The controller 312 may include one or more memories and/or one or more processors. The controller 312 may be configured to cause and control operations of the bonding device 300, such as operations described in connection with FIGS. 4-6.

As indicated above, FIG. 3 is provided as an example. Other examples may differ from what is described with regard to FIG. 3.

FIGS. 4-6 are diagrams illustrating an example 400 associated with ferromagnetic control of wafer bonding. Operations of example 400 may be performed by the bonding device 300 (e.g., by controller 312).

As shown in FIG. 4, the bonding device 300 may position a first semiconductor device on the first chuck 302 of the bonding device 300. The first chuck 302 may include one or more electromagnets 306, as described herein. The first semiconductor device may include a semiconductor wafer 402 (e.g., a silicon wafer) and a layer of ferromagnetic material 404 disposed on, or embedded in, the semiconductor wafer 402. In some implementations, the layer of ferromagnetic material 404 may be embedded in a carrier layer 406 that is disposed on the semiconductor wafer 402. For example, the carrier layer 406 may be a dielectric layer (e.g., a layer that comprises, consists of, or consists essentially of a dielectric material, such as glass). In some implementations, the layer of ferromagnetic material 404 may include a continuous (e.g., unitary) sheet of the ferromagnetic material 404. In some implementations, the layer of ferromagnetic material 404 may include multiple discrete regions of ferromagnetic material 404, as shown. These multiple discrete regions of ferromagnetic material 404 may be arranged in a grid. The ferromagnetic material 404 may comprise, consist of, or consist essentially of iron or an iron alloy, nickel or a nickel alloy, cobalt or a cobalt alloy, and/or a rare-earth metal alloy. In some implementations, the carrier layer 406 (e.g., the dielectric layer) may include a first layer and a second layer, and the layer of ferromagnetic material 404 may be disposed between the first layer and the second layer to embed the layer of ferromagnetic material 404 in the carrier layer 406. In some implementations, the carrier layer 406 (e.g., the dielectric layer) may be molded around the layer of ferromagnetic material 404 to embed the layer of ferromagnetic material 404 in the carrier layer 406.

Additionally, the bonding device 300 may position a second semiconductor device on the second chuck 304 of the bonding device 300. The second chuck 304 may include one or more electromagnets 306, as described herein. The second semiconductor device may include a semiconductor wafer 408 (e.g., a silicon wafer). A dielectric layer 410 may be disposed on the semiconductor wafer 408. In some implementations, the second semiconductor device may additionally, or alternatively, include a layer of ferromagnetic material, as described above.

In some implementations, the bonding device 300 may position the first semiconductor device and/or position the second semiconductor device using one or more picker devices (e.g., a pick-and-place device, a bond head, a robotic arm, or the like). Additionally, or alternatively, the bonding device 300 may position the first semiconductor device and/or position the second semiconductor device using one or more roller assemblies, conveyor assemblies, or the like. In some implementations, the bonding device 300 may align the first semiconductor device and/or the second semiconductor device (e.g., with each other) using an alignment device.

In some implementations, in connection with positioning the first semiconductor device, the bonding device 300 may activate the vacuum device 308, or an additional vacuum device, to apply a vacuum to the first chuck 302 to thereby retain the first semiconductor device on the first chuck 302. Additionally, or alternatively, the bonding device 300 may activate one or more electromagnets 306 to retain the first semiconductor device on the first chuck 302 (e.g., by interaction of magnetic fields produced by the electromagnets 306 with the layer of ferromagnetic material 404 of the first semiconductor device). That is, the bonding device 300 may control one or more magnetic fields, that interact with the layer of ferromagnetic material 404, to retain the first semiconductor device on the first chuck 302. In some implementations, in connection with positioning the second semiconductor device, the bonding device 300 may activate the vacuum device 308 to apply a vacuum to the second chuck 304 to thereby retain the second semiconductor device on the second chuck 304. After positioning the first semiconductor device and the second semiconductor device, the bonding device 300 may actuate the first chuck 302 and/or the second chuck 304 to bring the first chuck 302 and the second chuck 304 to within a particular distance of each other.

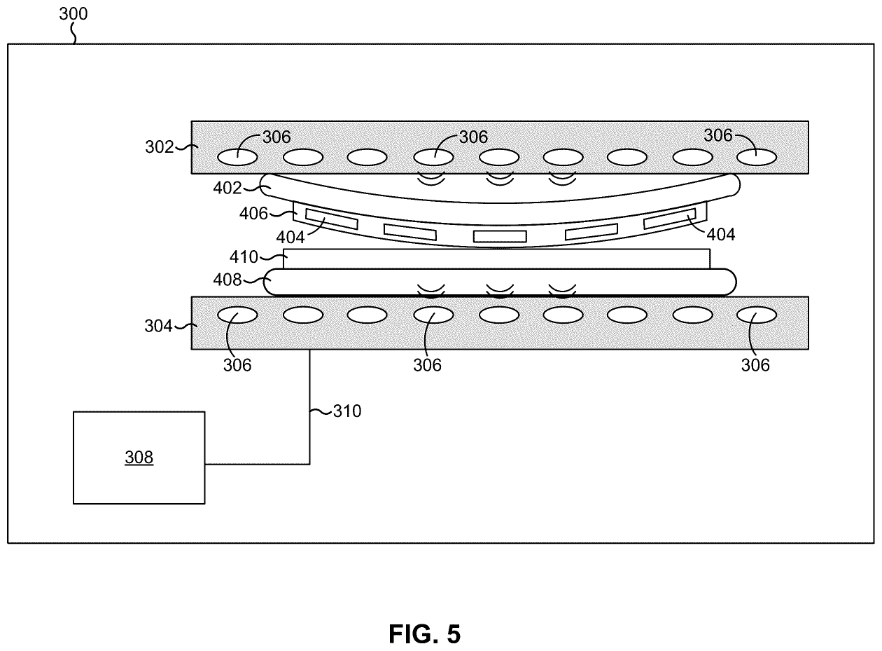

As shown in FIG. 5, the bonding device 300 may control one or more magnetic fields to interact with the layer of ferromagnetic material 404. For example, the bonding device 300 may control a state of activation of one or more of the electromagnets 306 to attract and/or repel the layer of ferromagnetic material 404. Controlling a state of activation of an electromagnet 306 may include activating the electromagnet 306, adjusting an intensity (e.g., a strength of a magnetic field) of the electromagnet 306, and/or deactivating the electromagnet 306. In some implementations, one or more electromagnets 306 of the first chuck 302 and one or more electromagnets 306 of the second chuck 304 may be activated concurrently (e.g., overlapping in time). In some implementations, one or more electromagnets 306 may repel the layer of ferromagnetic material 404 and one or more electromagnets 306 may attract the layer of ferromagnetic material 404 concurrently (e.g., overlapping in time).

Control of the magnetic fields (e.g., control of the states of activation of the electromagnets 306) may cause bonding of the first semiconductor device and the second semiconductor device. For example, the bonding device 300 may control the magnetic fields in a first manner (e.g., control states of activation of the electromagnets 306 in a first configuration) to initiate bonding of the first semiconductor device and the second semiconductor device, control magnetic fields in a second manner (e.g., control states of activation of the electromagnets 306 in a second configuration) to control further bonding (e.g., a bond wave) of the first semiconductor device and the second semiconductor device, and so forth.

To control the magnetic fields (e.g., to control states of activation of the electromagnets 306), the bonding device 300 may control the flow of electrical current to the electromagnets 306. In some implementations, as shown, controlling the magnetic fields (e.g., controlling states of activation of the electromagnets 306) to interact with the layer of ferromagnetic material 404 in a particular way may cause flexing of the first semiconductor device to result in contact between the first semiconductor device and the second semiconductor device. For example, the contact may be between a center of the first semiconductor device to a center of the second semiconductor device, as shown, or the contact may be between an edge of the first semiconductor device to an edge of the second semiconductor device.

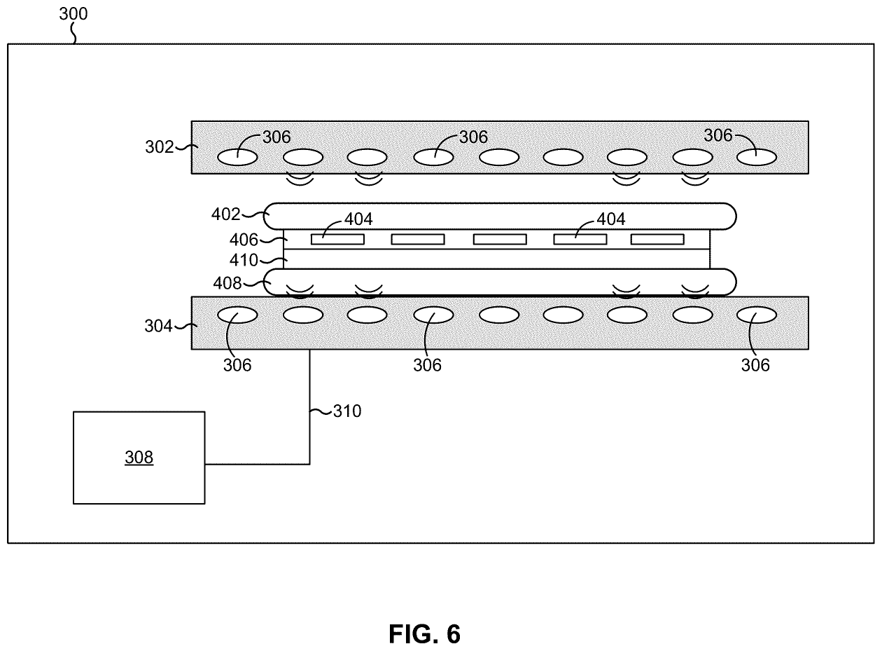

As shown in FIG. 6, the bonding device 300 may continue control of the magnetic fields (e.g., control of states of activation of the electromagnets 306) to complete bonding between the first semiconductor device and the second semiconductor device. In some implementations, the bonding device 300 may control states of activation of the electromagnets 306 according to a particular pattern, thereby achieving precise control over the bonding of the first semiconductor device and the second semiconductor device. For example, the bonding device 300 may control states of activation of the electromagnets 306 according to a first configuration to cause flexing of the first semiconductor device and initiate the bonding, control states of activation of the electromagnets 306 according to a second configuration to adjust the flexure of the first semiconductor device and continue the bonding, and so forth.

The electromagnets 306, which may be arranged in grids and located in the first chuck 302 and in the second chuck 304, as described herein, may provide multiple magnetic field zones to enable manipulation of the first semiconductor device in three dimensions. In this way, magnetic fields originating from the first chuck 302 and/or the second chuck 304 may enable pushing or pulling, in a vertical direction and in a horizontal direction, of the first semiconductor device to improve control over alignment, distortion (e.g., by controlling a strength of the magnetic fields), and deflection. Thus, a shape and/or a speed of a bond wave may be tightly controlled to thereby improve bond quality.

As indicated above, FIGS. 4-6 are provided as an example. Other examples may differ from what is described with regard to FIGS. 4-6.

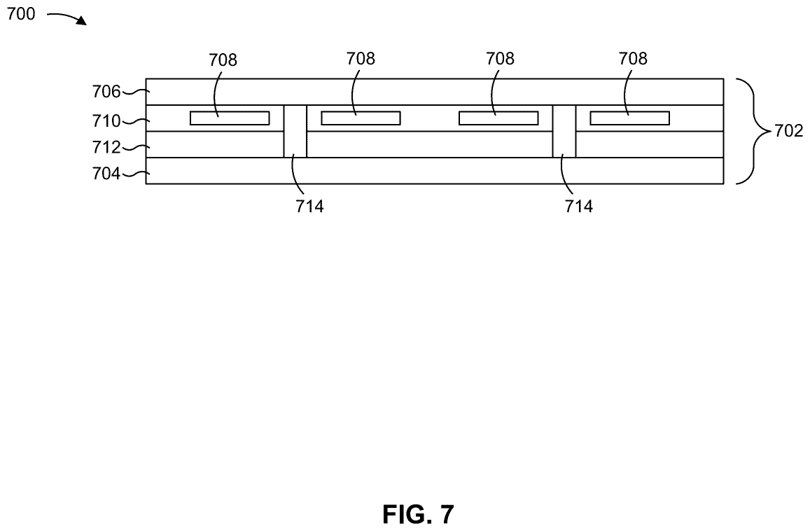

FIG. 7 is a diagram of an example semiconductor device assembly 700. The semiconductor device assembly 700 may be produced using the techniques described in connection with FIGS. 4-6. For example, after the first semiconductor device (e.g., a first wafer) and the second semiconductor device (e.g., a second wafer) have been bonded into a composite structure, the composite structure may be diced to achieve the semiconductor device assembly 700.

As shown, the semiconductor device assembly 700 may include a semiconductor die 702. The semiconductor die 702 may include a first active device layer 704 (e.g., corresponding to a portion of the semiconductor wafer 408) and a second active device layer 706 (e.g., corresponding to a portion of the semiconductor wafer 402). For example, the semiconductor device assembly 700 may be a three-dimensional integrated circuit (3DIC). In some implementations, the semiconductor device assembly 700 (e.g., the 3DIC) may be a memory device, as described herein.

The semiconductor device assembly 700 may include a layer of ferromagnetic material 708 (e.g., corresponding to a portion of the layer of ferromagnetic material 404) disposed between the first active device layer 704 and the second active device layer 706. The layer of ferromagnetic material 708 may include a continuous sheet of ferromagnetic material 708 or multiple discrete regions of ferromagnetic material 708, as described herein. In some implementations, the semiconductor device assembly 700 may include a carrier layer 710 (e.g., corresponding to a portion of the carrier layer 406), such as a dielectric layer, between the first active device layer 704 and the second active device layer 706, and the layer of ferromagnetic material 708 may be embedded in the carrier layer 710, as described herein. In some implementations, the semiconductor device assembly 700 may include a dielectric layer 712 (e.g., corresponding to a portion of the dielectric layer 410) between the first active device layer 704 and the second active device layer 706. Although described and shown in FIG. 7 as separate layers, the carrier layer 710 and the dielectric layer 712 (e.g., which may be separate layers prior to the bonding described herein) may be indistinguishable from one another due to the bonding described herein.

In some implementations, the first active device layer 704 and the second active device layer 706 may be electrically interconnected. For example, as shown, the semiconductor device assembly 700 may include one or more vias 714 (e.g., through-silicon vias (TSVs)) to electrically interconnect the first active device layer 704 and the second active device layer 706. In some implementations, the semiconductor device assembly 700 may be electrically connected to a circuit board, as described herein.

As indicated above, FIG. 7 is provided as an example. Other examples may differ from what is described with regard to FIG. 7.

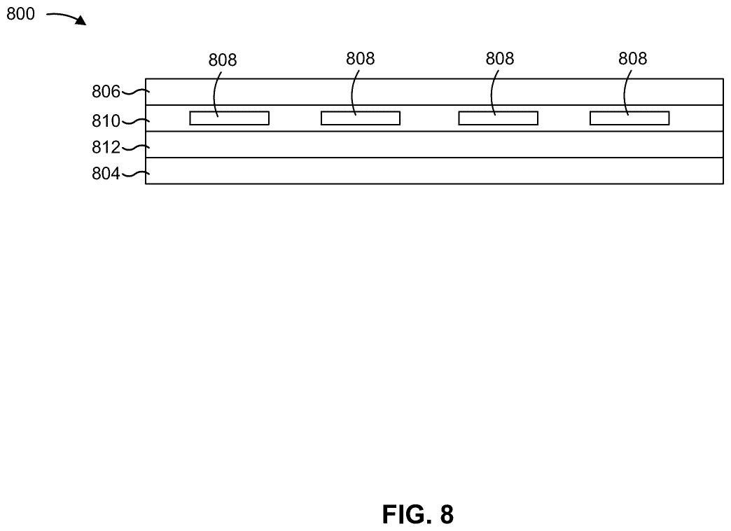

FIG. 8 is a diagram of an example semiconductor device assembly 800. The semiconductor device assembly 800 may be produced using the techniques described in connection with FIGS. 4-6. For example, after the first semiconductor device (e.g., a first wafer) and the second semiconductor device (e.g., a second wafer) have been bonded into a composite structure, the composite structure may be diced to achieve the semiconductor device assembly 800.

As shown, the semiconductor device assembly 800 may include a first semiconductor die 804 (e.g., corresponding to a portion of the wafer 408) and a second semiconductor die 806 (e.g., corresponding to a portion of the wafer 402) in a stacked arrangement with the first semiconductor die 804. In some implementations, the semiconductor device assembly 800 may be a memory device, as described herein.

The semiconductor device assembly 800 may include a layer of ferromagnetic material 808 (e.g., corresponding to a portion of the layer of ferromagnetic material 404) disposed between the first semiconductor die 804 and the second semiconductor die 806. The layer of ferromagnetic material 808 may include a continuous sheet of ferromagnetic material 808 or multiple discrete regions of ferromagnetic material 808, as described herein. In some implementations, the semiconductor device assembly 800 may include a carrier layer 810 (e.g., corresponding to a portion of the carrier layer 406), such as a dielectric layer, between the first semiconductor die 804 and the second semiconductor die 806, and the layer of ferromagnetic material 808 may be embedded in the carrier layer 810, as described herein. In some implementations, the semiconductor device assembly 800 may include a dielectric layer 812 (e.g., corresponding to a portion of the dielectric layer 410) between the first semiconductor die 804 and the second semiconductor die 806. Although described and shown in FIG. 8 as separate layers, the carrier layer 810 and the dielectric layer 812 (e.g., which may be separate layers prior to the bonding described herein) may be indistinguishable from one another due to the bonding described herein.

In some implementations, the first semiconductor die 804 and the second semiconductor die 806 may be electrically connected. In some implementations, the semiconductor device assembly 800 may be electrically connected to a circuit board, as described herein.

As indicated above, FIG. 8 is provided as an example. Other examples may differ from what is described with regard to FIG. 8.

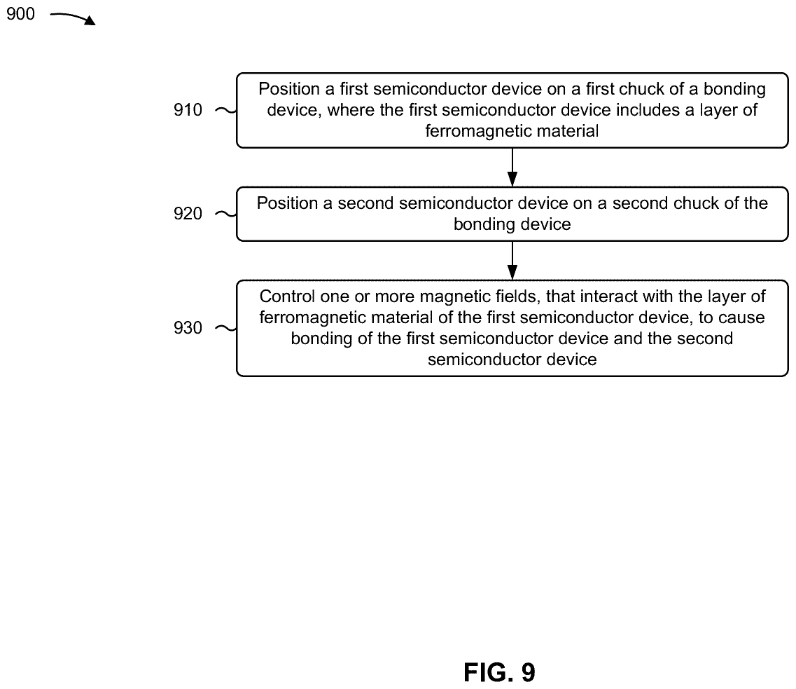

FIG. 9 is a flowchart of an example method 900 of forming an integrated assembly or memory device having a layer of ferromagnetic material. In some implementations, one or more process blocks of FIG. 9 may be performed by various semiconductor manufacturing equipment.

As shown in FIG. 9, the method 900 may include positioning a first semiconductor device on a first chuck of a bonding device, where the first semiconductor device includes a layer of ferromagnetic material (block 910). As further shown in FIG. 9, the method 900 may include positioning a second semiconductor device on a second chuck of the bonding device (block 920). As further shown in FIG. 9, the method 900 may include controlling one or more magnetic fields, that interact with the layer of ferromagnetic material of the first semiconductor device, to cause bonding of the first semiconductor device and the second semiconductor device (block 930).

The method 900 may include additional aspects, such as any single aspect or any combination of aspects described below and/or in connection with one or more other methods described elsewhere herein.

In a first aspect, at least one of the first chuck or the second chuck includes a plurality of electromagnets, and controlling the one or more magnetic fields includes controlling electrical current to the plurality of electromagnets.

In a second aspect, alone or in combination with the first aspect, controlling the one or more magnetic fields is to cause flexing of the first semiconductor device resulting in contact between the first semiconductor device and the second semiconductor device.

In a third aspect, alone or in combination with one or more of the first and second aspects, the first semiconductor device includes a first semiconductor wafer with the layer of ferromagnetic material disposed on the first semiconductor wafer, and the second semiconductor device includes a second semiconductor wafer.

In a fourth aspect, alone or in combination with one or more of the first through third aspects, the first semiconductor device further includes a dielectric layer disposed on the first semiconductor wafer, and the layer of ferromagnetic material is embedded in the dielectric layer.

In a fifth aspect, alone or in combination with one or more of the first through fourth aspects, the layer of ferromagnetic material includes multiple discrete regions of ferromagnetic material.

In a sixth aspect, alone or in combination with one or more of the first through fifth aspects, the method 900 includes controlling the one or more magnetic fields, that interact with the layer of ferromagnetic material of the first semiconductor device, to retain the first semiconductor device on the first chuck.

In a seventh aspect, alone or in combination with one or more of the first through sixth aspects, the method 900 includes applying a vacuum to the second chuck to retain the second semiconductor device on the second chuck.

In an eighth aspect, alone or in combination with one or more of the first through seventh aspects, the method 900 includes dicing a composite device resulting from bonding of the first semiconductor device and the second semiconductor device.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming the semiconductor device assembly 700 or 800, an integrated assembly that includes the semiconductor device assembly 700 or 800, any part described herein of the semiconductor device assembly 700 or 800, and/or any part described herein of an integrated assembly that includes the semiconductor device assembly 700 or 800. For example, the method 900 may include forming the layer of ferromagnetic material 708 or 808.

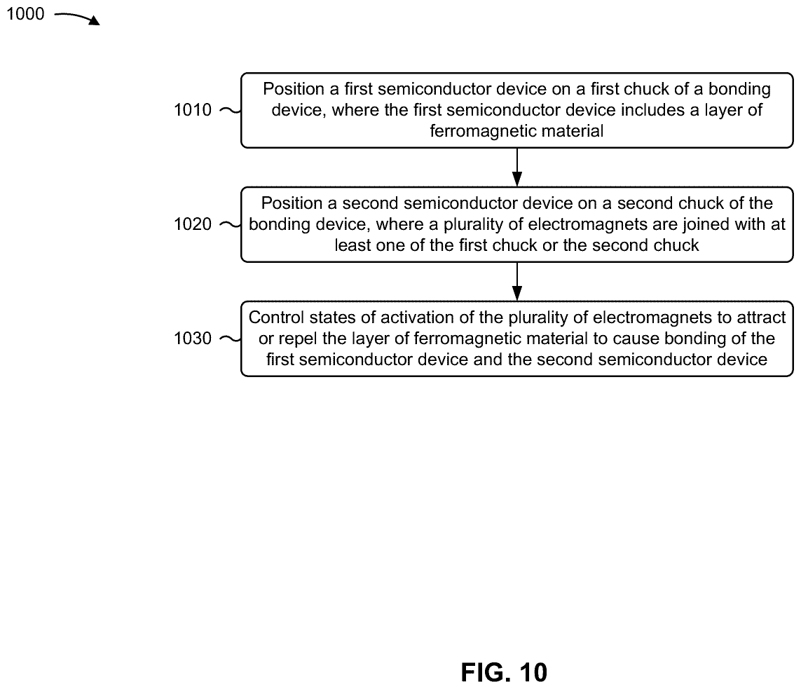

FIG. 10 is a flowchart of an example method 1000 of forming an integrated assembly or memory device having a layer of ferromagnetic material. In some implementations, one or more process blocks of FIG. 10 may be performed by various semiconductor manufacturing equipment.

As shown in FIG. 10, the method 1000 may include positioning a first semiconductor device on a first chuck of a bonding device, where the first semiconductor device includes a layer of ferromagnetic material (block 1010). As further shown in FIG. 10, the method 1000 may include positioning a second semiconductor device on a second chuck of the bonding device, where a plurality of electromagnets are joined with at least one of the first chuck or the second chuck (block 1020). As further shown in FIG. 10, the method 1000 may include controlling states of activation of the plurality of electromagnets to attract or repel the layer of ferromagnetic material to cause bonding of the first semiconductor device and the second semiconductor device (block 1030).

The method 1000 may include additional aspects, such as any single aspect or any combination of aspects described below and/or in connection with one or more other methods described elsewhere herein.

In a first aspect, controlling the states of activation of the plurality of electromagnets includes controlling electrical current to the plurality of electromagnets.

In a second aspect, alone or in combination with the first aspect, controlling the states of activation of the plurality of electromagnets is to cause flexing of the first semiconductor device resulting in contact between the first semiconductor device and the second semiconductor device.

In a third aspect, alone or in combination with one or more of the first and second aspects, the first semiconductor device includes a first semiconductor wafer with the layer of ferromagnetic material disposed on the first semiconductor wafer, and the second semiconductor device includes a second semiconductor wafer.

In a fourth aspect, alone or in combination with one or more of the first through third aspects, the first semiconductor device further includes a dielectric layer disposed on the first semiconductor wafer, and the layer of ferromagnetic material is embedded in the dielectric layer.

In a fifth aspect, alone or in combination with one or more of the first through fourth aspects, the layer of ferromagnetic material includes multiple discrete regions of ferromagnetic material.

In a sixth aspect, alone or in combination with one or more of the first through fifth aspects, the method 1000 includes controlling the states of activation of the plurality of electromagnets to retain the first semiconductor device on the first chuck.

In a seventh aspect, alone or in combination with one or more of the first through sixth aspects, the method 1000 includes applying a vacuum to the second chuck to retain the second semiconductor device on the second chuck.

In an eighth aspect, alone or in combination with one or more of the first through seventh aspects, the method 1000 includes dicing a composite device resulting from bonding of the first semiconductor device and the second semiconductor device.

Although FIG. 10 shows example blocks of the method 1000, in some implementations, the method 1000 may include additional blocks, fewer blocks, different blocks, or differently arranged blocks than those depicted in FIG. 10. In some implementations, the method 1000 may include forming the semiconductor device assembly 700 or 800, an integrated assembly that includes the semiconductor device assembly 700 or 800, any part described herein of the semiconductor device assembly 700 or 800, and/or any part described herein of an integrated assembly that includes the semiconductor device assembly 700 or 800. For example, the method 1000 may include forming the layer of ferromagnetic material 708 or 808.

In some implementations, a method includes positioning a first semiconductor device on a first chuck of a bonding device, wherein the first semiconductor device includes a layer of ferromagnetic material; positioning a second semiconductor device on a second chuck of the bonding device; and controlling one or more magnetic fields, that interact with the layer of ferromagnetic material of the first semiconductor device, to cause bonding of the first semiconductor device and the second semiconductor device.

In some implementations, a method includes positioning a first semiconductor device on a first chuck of a bonding device, wherein the first semiconductor device includes a layer of ferromagnetic material; positioning a second semiconductor device on a second chuck of the bonding device, wherein a plurality of electromagnets are joined with at least one of the first chuck or the second chuck; and controlling states of activation of the plurality of electromagnets to attract or repel the layer of ferromagnetic material to cause bonding of the first semiconductor device and the second semiconductor device.

In some implementations, a semiconductor device assembly includes a first active device layer of a semiconductor die; a second active device layer of the semiconductor die; and a layer of ferromagnetic material disposed between the first active device layer and the second active device layer.

In some implementations, a semiconductor device assembly includes a first semiconductor die; a second semiconductor die in a stacked arrangement with the first semiconductor die; and a layer of ferromagnetic material disposed between the first semiconductor die and the second semiconductor die.

In some implementations, a bonding device includes a first chuck to retain a first semiconductor device at a first surface of the first chuck; a second chuck to retain a second semiconductor device at a second surface of the second chuck, wherein the first surface of the first chuck faces the second surface of the second chuck; and a plurality of electromagnets joined with at least one of the first chuck or the second chuck.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
positioning a first semiconductor device on a first chuck of a bonding device,
wherein the first semiconductor device includes a layer of ferromagnetic material;
positioning a second semiconductor device on a second chuck of the bonding device; and
controlling one or more magnetic fields, that interact with the layer of ferromagnetic material of the first semiconductor device, to cause bonding of the first semiconductor device and the second semiconductor device.

2. The method of claim 1, wherein at least one of the first chuck or the second chuck includes a plurality of electromagnets, and
wherein controlling the one or more magnetic fields comprises:
controlling electrical current to the plurality of electromagnets.

3. The method of claim 1, wherein controlling the one or more magnetic fields is to cause flexing of the first semiconductor device resulting in contact between the first semiconductor device and the second semiconductor device.

4. The method of claim 1, wherein the first semiconductor device includes a first semiconductor wafer with the layer of ferromagnetic material disposed on the first semiconductor wafer, and the second semiconductor device includes a second semiconductor wafer.

5. The method of claim 4, wherein the first semiconductor device further includes a dielectric layer disposed on the first semiconductor wafer, and
wherein the layer of ferromagnetic material is embedded in the dielectric layer.

6. The method of claim 4, wherein the layer of ferromagnetic material includes multiple discrete regions of ferromagnetic material.

7. The method of claim 1, further comprising:
controlling the one or more magnetic fields, that interact with the layer of ferromagnetic material of the first semiconductor device, to retain the first semiconductor device on the first chuck.

8. The method of claim 1, further comprising:
applying a vacuum to the second chuck to retain the second semiconductor device on the second chuck.

9. A method, comprising:
positioning a first semiconductor device on a first chuck of a bonding device,
wherein the first semiconductor device includes a layer of ferromagnetic material;
positioning a second semiconductor device on a second chuck of the bonding device,
wherein a plurality of electromagnets are joined with at least one of the first chuck or the second chuck; and
controlling states of activation of the plurality of electromagnets to attract or repel the layer of ferromagnetic material to cause bonding of the first semiconductor device and the second semiconductor device.

10. The method of claim 9, wherein controlling the states of activation of the plurality of electromagnets comprises:
controlling electrical current to the plurality of electromagnets.

11. The method of claim 9, wherein controlling the states of activation of the plurality of electromagnets is to cause flexing of the first semiconductor device resulting in contact between the first semiconductor device and the second semiconductor device.

12. The method of claim 9, wherein the first semiconductor device includes a first semiconductor wafer with the layer of ferromagnetic material disposed on the first semiconductor wafer, and the second semiconductor device includes a second semiconductor wafer.

13. The method of claim 12, wherein the first semiconductor device further includes a dielectric layer disposed on the first semiconductor wafer, and
wherein the layer of ferromagnetic material is embedded in the dielectric layer.

14. The method of claim 12, wherein the layer of ferromagnetic material includes multiple discrete regions of ferromagnetic material.

15. The method of claim 9, further comprising:
controlling the states of activation of the plurality of electromagnets to retain the first semiconductor device on the first chuck.

16. The method of claim 9, further comprising:
applying a vacuum to the second chuck to retain the second semiconductor device on the second chuck.

17. A semiconductor device assembly, comprising:
a first active device layer of a semiconductor die;
a second active device layer of the semiconductor die; and
a layer of ferromagnetic material disposed between the first active device layer and the second active device layer.

18. The semiconductor device assembly of claim 17, wherein the layer of ferromagnetic material includes multiple discrete regions of ferromagnetic material.

19. The semiconductor device assembly of claim 17, further comprising:
a dielectric layer between the first active device layer and the second active device layer.

20. The semiconductor device assembly of claim 19, wherein the layer of ferromagnetic material is embedded in the dielectric layer.

21. The semiconductor device assembly of claim 17, wherein the first active device layer and the second active device layer are electrically interconnected.

22. The semiconductor device assembly of claim 17, wherein the semiconductor device assembly is a memory device.

23. A semiconductor device assembly, comprising:
a first semiconductor die;
a second semiconductor die in a stacked arrangement with the first semiconductor die; and
a layer of ferromagnetic material disposed between the first semiconductor die and the second semiconductor die.

24. The semiconductor device assembly of claim 23, wherein the layer of ferromagnetic material includes multiple discrete regions of ferromagnetic material.

25. The semiconductor device assembly of claim 23, further comprising:
a dielectric layer between the first semiconductor die and the second semiconductor die.

26. The semiconductor device assembly of claim 25, wherein the layer of ferromagnetic material is embedded in the dielectric layer.

27. The semiconductor device assembly of claim 23, wherein the semiconductor device assembly is a memory device.

28. A bonding device, comprising:
a first chuck to retain a first semiconductor device at a first surface of the first chuck;
a second chuck to retain a second semiconductor device at a second surface of the second chuck,
wherein the first surface of the first chuck faces the second surface of the second chuck; and
a plurality of electromagnets joined with at least one of the first chuck or the second chuck.

29. The bonding device of claim 28, wherein the plurality of electromagnets include a first plurality of electromagnets joined with the first chuck, and a second plurality of electromagnets joined with the second chuck.

30. The bonding device of claim 29, wherein the first plurality of electromagnets are arranged in a grid and the second plurality of electromagnets are arranged in a grid.

31. The bonding device of claim 28, wherein the plurality of electromagnets are configured to be individually addressable.

32. The bonding device of claim 28, wherein the plurality of electromagnets are configured to generate one or more magnetic fields of a strength sufficient to repel or attract a ferromagnetic material layer of the first semiconductor device.

33. The bonding device of claim 28, further comprising:
a vacuum device; and
a vacuum line connecting the vacuum device and the second chuck.

34. The bonding device of claim 33, wherein the second chuck includes a plurality of openings in fluid communication with the vacuum line.
